(19) United States
(12) Patent Application Publication
(10) Pub. No.: US 2026/0343767 A1
(43) Pub. Date: Oct. 29, 2026

(54) GUIDE FILM, METHOD OF MANUFACTURING ELECTRONIC DEVICE BY USING THE GUIDE FILM, AND ELECTRONIC DEVICE MANUFACTURED BY THE METHOD

(71) Applicant: Samsung Display Co., LTD., Yongin-si (KR)

(72) Inventors: Young Min JUNG, Yongin-si (KR); Min Gwan KIM, Yongin-si (KR); Sang Mi LEE, Yongin-si (KR); Seong Won LIM, Yongin-si (KR); Ji Hoon OH, Yongin-si (KR); Dong Su YEE, Yongin-si (KR)

(21) Appl. No.: 19/384,153

(22) Filed: Nov. 10, 2025

(30) Foreign Application Priority Data
Apr. 25, 2025 (KR) 10-2025-0054862

(51) Int. Cl. H05K 5/03; B32B 3/26; B32B 3/30; B32B 7/06; B32B 7/12; B32B 27/36; G04B 39/00

(52) U.S. Cl. CPC H05K 5/03; B32B 3/266; B32B 3/30; B32B 7/06; B32B 7/12; B32B 27/36; G04B 39/00; B32B 2457/20

(57) ABSTRACT

A guide film includes a film base including an intermediate portion, side portions formed on opposite sides of the intermediate portion, and an opening area directly next (adjacent) to the intermediate portion.

### CROSS RERERENCE TO A RELATED APPLICATION

This application claims priority to Korean Patent Application Number 10-2025-0054862, filed on April 25, 2025, and all the benefits accruing therefrom under 35 U.S.C. §119, the content of which in its entirety is herein incorporated by reference.

### BACKGROUND

### 1. Field

The disclosure generally relates to a guide film, a method of manufacturing an electronic device using the guide film, and an electronic device manufactured by the method of manufacturing the electronic device.

### 2. DESCRIPTION OF RELATED ART

Electronic devices may provide various functions and conveniences to users. For example, electronic devices are applicable to various fields, such as wearable devices, and the scope of application is expanding as technology advances.

### SUMMARY

An electronic device may include a display panel to provide visual information to a user, and may further include a cover window. When the display panel and the cover window are not closely coupled (e.g., bonded) to each other, the user experience may be negatively impacted, and the reliability and durability of the device may be compromised, thereby creating a risk of shortening the lifespan of the device.

An embodiment of the disclosure provides a guide film, a method of manufacturing an electronic device using the guide film, and an electronic device manufactured by the method of manufacturing the electronic device, in which a display panel and a cover window included in the electronic device may be closely coupled (e.g., bonded).

An embodiment of the disclosure provides a guide film, a method of manufacturing an electronic device using the guide film, and an electronic device manufactured by the method of manufacturing the electronic device, in which the convenience of a process for coupling a display panel and a cover window may be improved, and the reliability of the process may be improved by precisely aligning the display panel.

In an embodiment of the disclosure, a guide film may include a film base including an intermediate portion and side portions formed on opposite sides of the intermediate portion. An opening area is defined directly next (adjacent) to the intermediate portion.

In an embodiment, the side portions may include a first side portion and a second side portion, and the intermediate portion may be disposed between the first side portion and the second side portion relative to a longitudinal direction of the guide film, and may form a panel placement area in which a display panel is disposed.

In an embodiment, the intermediate portion and the display panel may have a same shape as each other, and the panel placement area may have an area greater than or equal to a lower surface of the display panel.

In an embodiment, when the display panel may be disposed in the panel placement area, a lower surface of the display panel may be supported by the intermediate portion, and at least a portion of the lower surface of the display panel may be opened by the opening area.

In an embodiment, the guide film may further include: an adhesive layer disposed on a portion of the film base, and a temporary cover portion removably covering the adhesive layer.

In an embodiment, the film base may include a first film base and a film opening area defined in the first film base and exposing the first film base, the adhesive layer may be disposed on the first film base in the film opening area, and the temporary cover portion may include an adhesive covering portion covering the panel placement area and a handle portion connected to the adhesive covering portion and extending outward from the intermediate portion.

In an embodiment, the opening area may extend in a longitudinal direction of the guide film and penetrate the film base at each of the side portions.

In an embodiment, the opening area may have a width decreasing toward the intermediate portion.

In an embodiment, a part of the opening area may be surrounded by the side portions, and another part of the opening area may be surrounded by the intermediate portion, and the opening area may define a groove structure recessed into a part of the intermediate portion.

In an embodiment, the side portions may include a first side portion and a second side portion, the opening area may include a first opening area defined in the first side portion and a second opening area defined in the second side portion, and the first opening area and the second opening area may be symmetrical with respect to a central virtual line extending in a width direction of the guide film and passing through a center of the intermediate portion.

In an embodiment, the opening area may include a plurality of opening areas, and each of the side portions may include a wing portion formed between the plurality of opening areas in a width direction of the guide film.

In an embodiment, the guide film may further include a cavity including a groove structure defined in at least a part of the intermediate portion, the cavity being visually identifiable.

In plan view, the cavity may include a first cavity defined in an upper left part of the intermediate portion, a second cavity defined in a lower left part of the intermediate portion, a third cavity defined in an upper right part of the intermediate portion, and a fourth cavity defined in a lower right part of the intermediate portion.

In an embodiment of the disclosure, a method of manufacturing an electronic device may include providing a guide film including a film base which includes an intermediate portion and side portions formed on opposite sides of the intermediate portion and in which an opening area directly next (adjacent) to the intermediate portion is defined, disposing a display panel on the guide film, and coupling the display panel and a cover window portion.

In an embodiment, the guide film further may include: an adhesive layer disposed on a portion of the film base, and a temporary cover portion removably covering the adhesive layer, the providing the guide film may include securing both end portions of the guide film by a clamp portion and covering the adhesive layer by the temporary cover portion, and the disposing the display panel may include separating the temporary cover portion from the adhesive layer to expose the adhesive layer and disposing the display panel on the adhesive layer.

In an embodiment, the guide film may further include a cavity including a groove structure defined in at least a part of the intermediate portion, the cavity being visually identifiable, and the disposing the display panel may include determining the guide film using the cavity.

In an embodiment, in the disposing the display panel, a portion of the display panel may overlap with the opening area and another portion of the display panel may overlap with the intermediate portion in a plan view.

In an embodiment, in the disposing the display panel, the display panel may be disposed at a fixed position relative to the guide film, an end portion of the display panel may not protrude outward beyond a virtual line, and the virtual line may be defined along side surfaces of the side portions extending in a longitudinal direction of the guide film.

The method may further include separating the display panel from the guide film, the cover window portion may include a first portion and a second portion integral with the first portion and including a curved area and surrounding edges of the first portion, and at least a part of the second portion may extend in a thickness direction of the display panel.

The electronic device may be manufactured by the method, in which the cover window portion is inwardly curved toward the display panel.

### BRIEF DESCRIPTION OF THE DRAWINGS

The above and other features of embodiments of the disclosure will become more apparent by describing in further detail embodiments thereof with reference to the accompanying drawings, in which:

FIG. 1 is a schematic block diagram illustrating an embodiment of an electronic device;

FIG. 2 is a schematic perspective view illustrating an embodiment of a watch device;

FIG. 3 is a schematic plan view illustrating an embodiment of a watch device;

FIG. 4 is a schematic cross-sectional view illustrating an embodiment of a watch device;

FIG. 5 is a schematic perspective view illustrating an embodiment of a display panel and a circuit board portion;

FIGS. 6-11 are schematic perspective views illustrating an embodiment of a guide film;

FIG. 12 is a schematic flowchart illustrating an embodiment of a method of manufacturing an electronic device using a guide film; and

FIGS. 13-21 are schematic diagrams illustrating an embodiment of respective operations of a method of manufacturing an electronic device using a guide film.

### DETAILED DESCRIPTION

As the disclosure allows for various changes and numerous embodiments, particular embodiments will be illustrated in the drawings and described in detail in the written description. However, this is not necessarily intended to limit the disclosure to particular modes of practice, and it is to be appreciated that all changes, equivalents, and substitutes that do not depart from the spirit and technical scope of the disclosure are encompassed in the disclosure.

It will be understood that, although the terms “first”, “second”, etc. may be used herein to describe various elements, these elements should not be limited by these terms. These terms are only used to distinguish one element from another element. For instance, a first element discussed below could be termed a second element without departing from the scope of the disclosure. Similarly, the second element could also be termed the first element. In the disclosure, the singular forms are intended to comprise the plural forms as well, unless the context clearly indicates otherwise.

It will be further understood that the terms “comprise”, “comprise”, “have”, etc. when used in the disclosure, specify the presence of stated features, integers, steps, operations, elements, components, and/or combinations of them but do not preclude the presence or addition of one or more other features, integers, steps, operations, elements, components, and/or combinations thereof. Furthermore, in case that a first part such as a layer, a film, a region, or a plate is disposed “on” a second part, the first part may be not only “directly on” the second part but a third part may intervene between them. In addition, when it is expressed that a first part such as a layer, a film, a region, or a plate is formed on a second part, the surface of the second part on which the first part is formed is not necessarily limited to an upper surface of the second part but may include other surfaces such as a side surface or a lower surface of the second part. To the contrary, in case that a first part such as a layer, a film, a region, or a plate is “under” a second part, the first part may be not only “directly under” the second part but a third part may intervene between them.

Hereinafter, a guide film in an embodiment, a method of manufacturing an electronic device using the guide film, and an electronic device manufactured by the method of manufacturing the electronic device will be described with reference to the accompanying drawings.

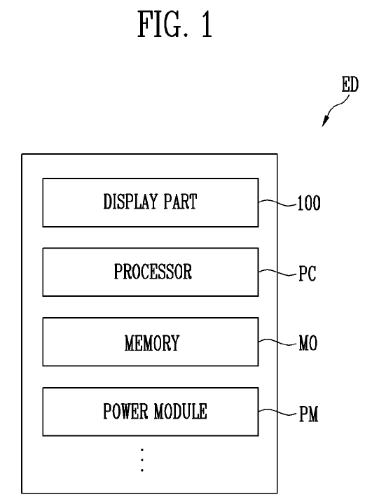

FIG. 1 is a schematic block diagram illustrating an embodiment of an electronic device ED.

Referring to FIG. 1, the electronic device ED is provided. The electronic device ED may be applicable to various examples. In an embodiment, the electronic device ED may include a wearable electronic device including a display module, such as a watch device (e.g., a smart watch), smart glasses, or a head-mounted display, and an automotive electronic device including a display module, such as an instrument cluster, a center fascia, a center information display (“CID”) disposed on a dashboard, or a room mirror display of a vehicle as well as an electronic device for displaying images, such as a smartphone, a tablet personal computer, a laptop, a television, or a desk monitor, for example.

In an embodiment, the electronic device ED includes a display part 100. The electronic device ED may further include a processor PC, a memory MO, and a power module PM.

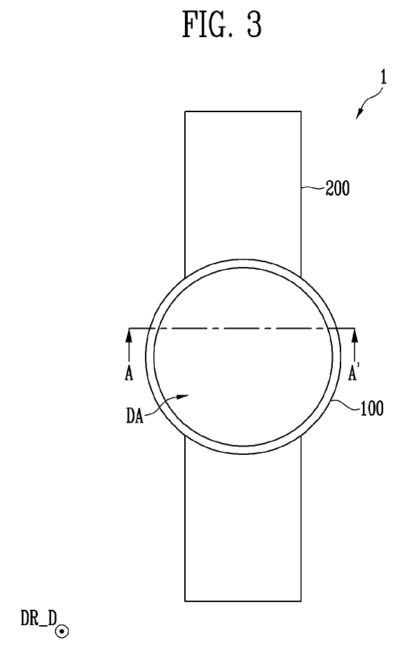

The display part 100 may provide image data including visual information. In an embodiment, the display part 100 may further include a cover window portion CV having at least a partially curved shape (refer to FIG. 3).

The processor PC may include at least one of a central processing unit (“CPU”), an application processor (“AP”), a graphic processing unit (“GPU”), a communication processor (“CP”), an image signal processor (“ISP”), and a controller. The processor PC may be electrically connected to the display part 100.

The memory MO may store data information for operations of the processor PC or the display part 100. When the processor PC executes an application stored in the memory MO, image data signals and/or input control signals may be transferred to the display part 100, and the display part 100 may process the received signals to output image information via a display screen.

The power module PM may include a power supply module, such as a power adapter or a battery unit, and a power conversion module which converts power supplied by the power supply module to generate power desired for operations of the electronic device ED. The power module PM may provide power to the display part 100.

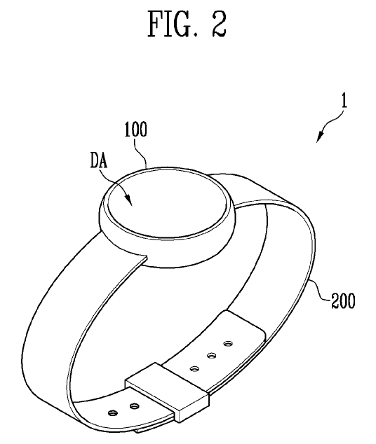

For convenience of explanation, an embodiment in which the display part 100 is applied to a watch device 1 (refer to FIG. 2) is described below as one of embodiments in which the electronic device ED including the display part 100 including the cover window portion CV having at least a partially curved shape is applied. However, the application embodiment of the electronic device ED is not limited thereto. This embodiment may be applied to various examples to which the electronic device ED is applicable, including those described above.

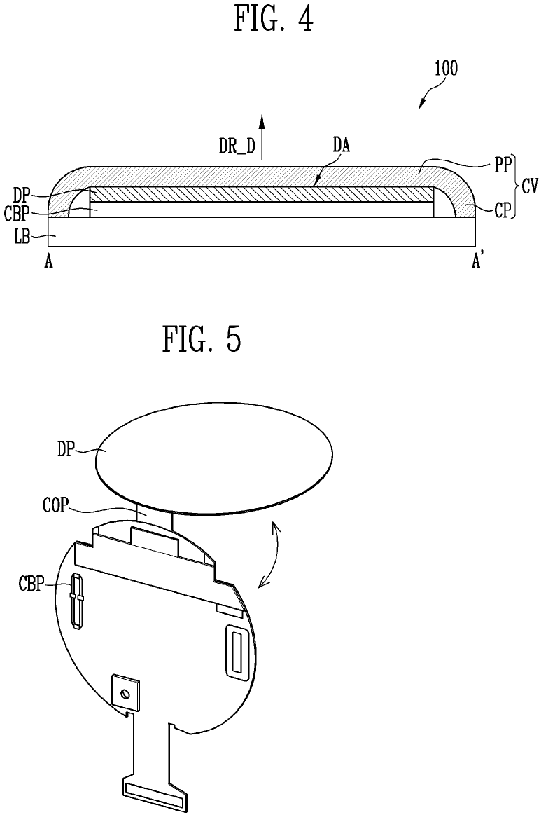

FIG. 2 is a schematic perspective view illustrating an embodiment of the watch device 1. FIG. 3 is a schematic plan view illustrating the watch device 1. FIG. 4 is a schematic cross-sectional view illustrating the watch device 1. FIG. 4 is a schematic cross-sectional view taken along line A-A’ of FIG. 3. FIG. 5 is a schematic perspective view illustrating a display panel and a circuit board portion.

Referring to FIGS. 2 to 5, the watch device 1 may be a wearable electronic device. In an embodiment, the watch device 1 may include the display part 100 and a strap part 200, for example.

The display part 100 may include a display area DA to which a display panel DP (e.g., a display device) is applied to provide image data including visual information along a display direction DR_D via the display area DA.

The strap part 200 may be disposed (e.g., mounted) on a wrist of a user. The strap part 200 may be connected to the display part 100. The strap part 200 may include a wearing portion which is worn on the wrist of the user and a connecting portion which connects a portion of the strap part 200 to another portion. The material of the strap part 200 is not limited to any particular example and may be worn on the wrist in various ways.

The user may mount the watch device 1 on the wrist of the user using the strap part 200. Accordingly, the display part 100 may be provided on the wrist of the user using the strap part 200 and may provide visual information to the user.

The display part 100 may have various shapes in a plan view. In an embodiment, the display part 100 (or the display area DA) may have a curved shape, for example. The display part 100 (or the display area DA) may have a circular shape or an elliptical shape. In another embodiment, the display part 100 (or the display area DA) may have a polygonal shape. The display part 100 (or the display area DA) may have a quadrangular shape, e.g., rectangular shape with rounded corners (e.g., a rounded rectangle).

For ease of explanation, an embodiment in which the display part 100 (or the display area DA) has a circular shape will be described below.

In an embodiment, the display part 100 may include a lower base LB, the display panel DP, a circuit board portion CBP, and the cover window portion CV.

The lower base LB may form part of a housing of the display part 100. The lower base LB may be disposed at a lower portion of the display panel DP (or the circuit board portion CBP) where the cover window portion CV is not disposed. The lower base LB may include a rigid material (e.g., metal, plastic, etc.).

The display panel DP may emit light. The display panel DP may be disposed between the lower base LB and the cover window portion CV. The display panel DP may include various light sources. In an embodiment, the display panel DP may be an organic light-emitting panel including an organic light-emitting element, or an inorganic light-emitting panel including an inorganic light-emitting element (e.g., a micro light-emitting diode (“LED”)), for example. However, the disclosure is not limited to a particular example.

The circuit board portion CBP may be disposed between the lower base LB and the display panel DP. The circuit board portion CBP may be disposed on a rear surface of the display panel DP. The circuit board portion CBP may be electrically connected to the wiring of the display panel DP via a connection portion COP electrically connected to a pad (e.g., a pad terminal) formed on a portion of the display panel DP.

At least a part of the connection portion COP may be bent, a first end of the connection portion COP may be disposed on a portion of the display panel DP, and a second end of the connection portion COP may be disposed on a part of the circuit board portion CBP. The connection portion COP may have a chip-on-film structure, but the disclosure is not limited thereto. As the connection portion COP is bent, the circuit board portion CBP may be provided on the rear surface of the display panel DP.

The circuit board portion CBP may supply electrical signals (data, driver signals, etc.) for controlling the operation of the pixels provided in the display panel DP through the connection portion COP. The pixels formed in the display panel DP may emit light based on the supplied electrical signals or the like.

In an embodiment, at least a part of the circuit board portion CBP may be included in the processor PC, or the circuit board portion CBP may be disposed separately from the processor PC. However, this disclosure is not limited to any particular example.

The circuit board portion CBP may be connected to an end portion of the display panel DP through the connection portion COP. The circuit board portion CBP may be disposed on the rear surface of the display panel DP as the connection portion COP is bent after the display panel DP is attached to the cover window portion CV.

The cover window portion CV may be disposed over the display panel DP. The cover window portion CV may form an outer periphery (e.g., an outermost periphery) of the display part 100 based on the display direction DR_D along which the display area DA is formed and visual information is output.

The cover window portion CV may be coupled (e.g., bonded) to an upper surface of the display panel DP. In an embodiment, a transparent adhesive layer (not shown) may be interposed between the cover window portion CV and the display panel DP that are coupled (e.g., bonded) to each other by the transparent adhesive layer. The transparent adhesive layer may include an acrylic-based or epoxy-based material. However, the disclosure is not limited thereto.

The cover window portion CV may form a space in which the display panel DP is disposed. The cover window portion CV may be open at the bottom such that the display panel DP may be provided through a rear surface of the cover window portion CV. In an embodiment, the cover window portion CV may have an approximately flat-dome shape which is open at the bottom, for example. However, the disclosure is not limited thereto.

The cover window portion CV may include a portion which is curved at least in part. The cover window portion CV may have at least a partially curved shape (e.g., a cross-sectional shape). In an embodiment, the cover window portion CV may include a curved surface, for example. The cover window portion CV may be curved inward along a direction opposite to the display direction DR_D (e.g., the direction in which the rear surface of the display panel DP faces). At least a portion of an outer surface of the cover window portion CV may form a convex surface.

The cover window portion CV may include a first portion PP having a relatively flat outer surface and formed at the center of the display part 100 and around the center, and a second portion CP formed on an outer periphery of the first portion PP and including at least a partially curved region. An inner surface of the first portion PP may be coupled (e.g., bonded) to the display panel DP. The second portion CP may form a side portion of the cover window portion CV. At least a part of the second portion CP may extend in a thickness direction of the display panel DP. In an embodiment, the second portion CP may be integral with the first portion PP, and may surround an entirety of the edges of the first portion PP, for example.

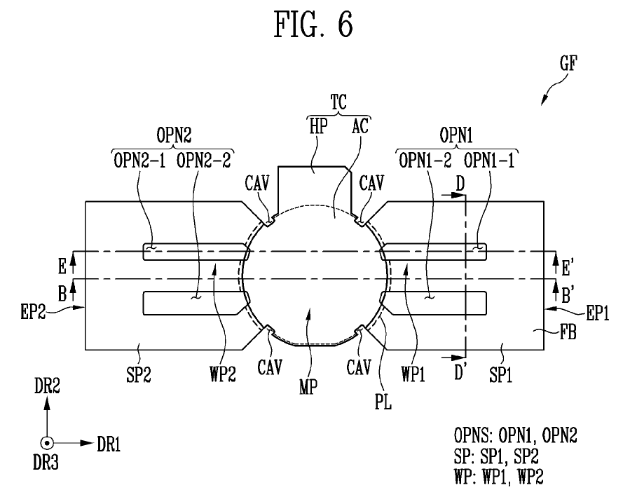

Referring to FIGS. 6-11, a guide film GF which may be applied (e.g., used) during a process of coupling the display panel DP and the cover window portion CV will be described. For convenience of explanation, descriptions which may overlap with the foregoing description will be schematically illustrated or omitted.

FIGS. 6-11 are schematic plan views illustrating an embodiment of the guide film GF.

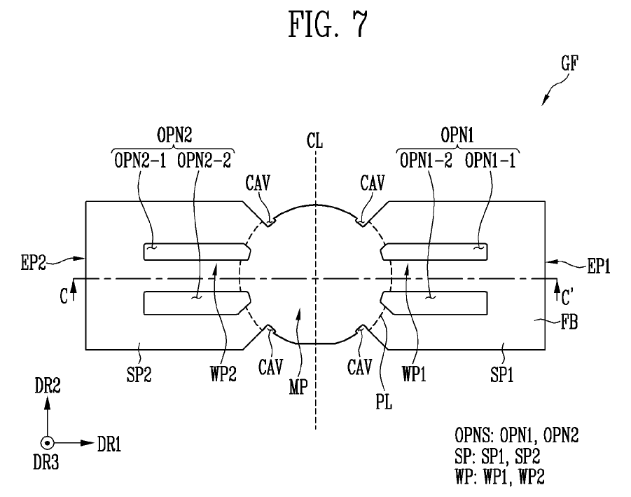

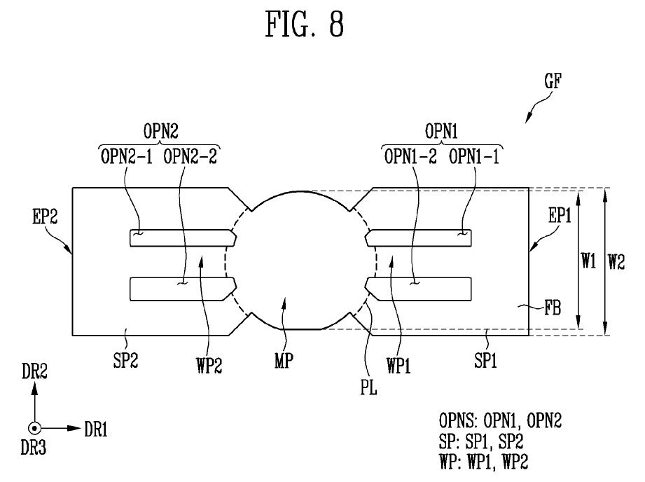

FIGS. 6-8 are schematic plan views illustrating an embodiment of the guide film GF. FIG. 6 schematically illustrates the guide film GF to which a temporary cover portion TC is attached. FIGS. 7-8 schematically illustrate the guide film GF from which the temporary cover portion TC is removed. FIG. 7 schematically illustrates an embodiment in which the guide film GF includes a cavity CAV, and FIG. 8 schematically illustrates an embodiment in which the guide film GF does not include the cavity CAV.

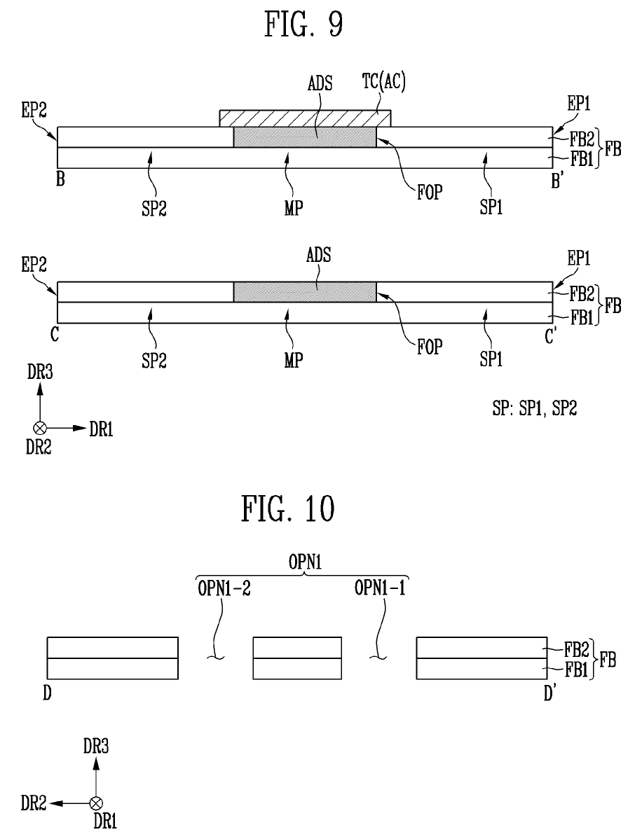

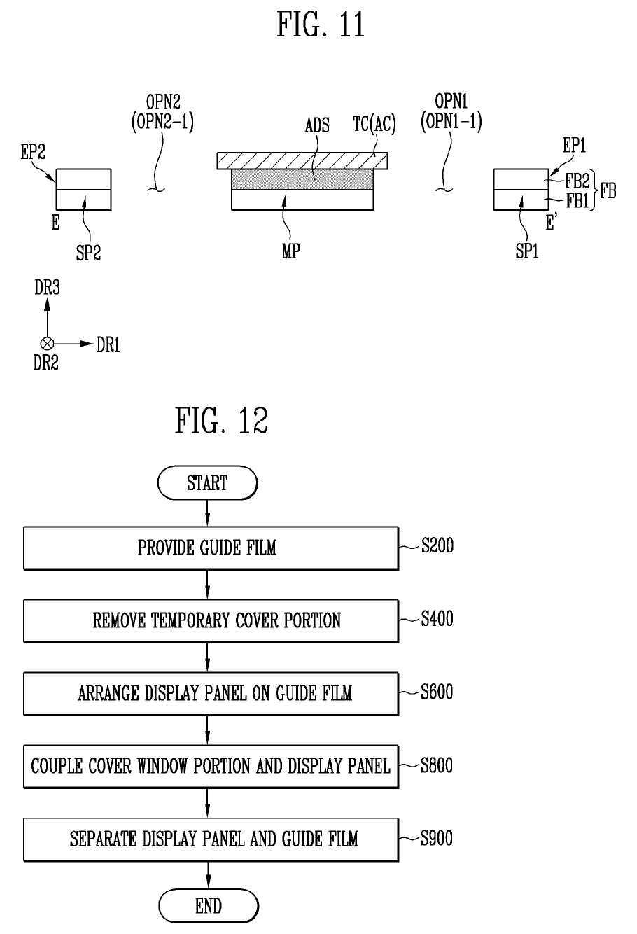

FIGS. 9-11 are schematic cross-sectional views illustrating an embodiment of the guide film GF. FIG. 9 illustrates a cross-section taken along line B-B’ of FIG. 6 and a cross-section along line C-C’ of FIG. 7. FIG. 10 is a cross-sectional diagram taken along line D-D’ of FIG. 6. FIG. 11 is a cross-sectional diagram taken along line E to E’ of FIG. 6.

Referring to FIGS. 6-11, the guide film GF is provided. The guide film GF may have a film form, and may form a region to which the display panel DP may be coupled (e.g., bonded) depending on whether the temporary cover portion TC is removed or attached.

The guide film GF may include a film base FB, an adhesive layer ADS, and the temporary cover portion TC.

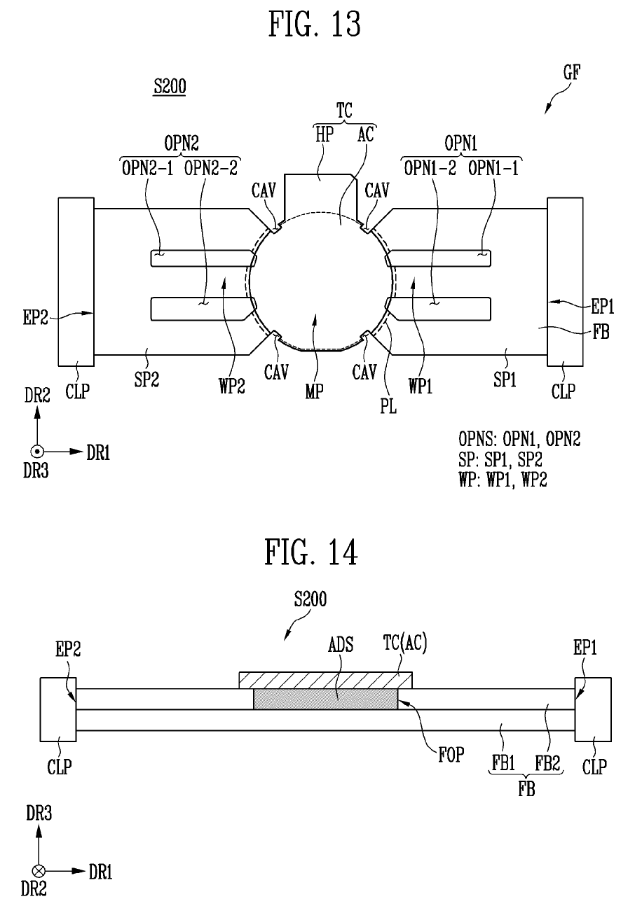

The film base FB may form the base of the guide film GF. The film base FB may extend in a first direction DR1. The film base FB may include a first end portion EP1 and a second end portion EP2, and the film base FB may be clamped by a clamp portion CLP (refer to FIG. 13) at each of the first end portion EP1 and the second end portion EP2.

In the disclosure, the first direction DR1 may be a longitudinal direction of the guide film GF (or the film base FB). A second direction DR2 may be a width direction of the guide film GF (or the film base FB). A third direction DR3 may be a thickness direction of the guide film GF (or the film base FB).

The film base FB may include various materials. In an embodiment, the film base FB may include a polymeric material, such as various plastics, for example. In an embodiment, the film base FB may include polyethylene terephthalate (“PET”), for example. However, the disclosure is not limited thereto.

The film base FB may include a plurality of layers. In an embodiment, the film base FB may include a first film base FB1 and a second film base FB2 on the first film base FB, for example.

A portion of the second film base FB2 may not be disposed on the first film base FB1 and may define a film opening area FOP. The film opening area FOP may expose the first film base FB1. The film opening area FOP may define a space in which the adhesive layer ADS is disposed. In an embodiment, the film opening area FOP may be defined in an intermediate portion MP, and the adhesive layer ADS may be provided within a panel placement area PL formed by the intermediate portion MP, for example.

In an embodiment, the film base FB may include the intermediate portion MP, a side portion SP forming a wing portion WP, and an opening area OPN.

The intermediate portion MP may be disposed between a first side portion SP1 and a second side portion SP2 on the basis of the first direction DR1. The intermediate portion MP may form the panel placement area PL. The intermediate portion MP (or the panel placement area PL) may have the same shape as that of the shape of the display panel DP to be disposed on the guide film GF in a plan view. In an embodiment, the intermediate portion MP (or the panel placement area PL) may have a circular shape, for example.

The panel placement area PL formed by the intermediate portion MP may have an area greater than or equal to a lower surface of the display panel DP. In an embodiment, the adhesive layer ADS may be disposed on the intermediate portion MP, for example. In addition, when the panel placement area PL has an area greater than or equal to the display panel DP, the area on which the adhesive layer ADS is disposed may have an area greater than or equal to the display panel DP. The display panel DP may be closely attached to the film base FB through the adhesive layer ADS, and a process deviation for attaching the display panel DP to the guide film GF may be compensated, thereby improving process convenience.

In an embodiment (FIGS. 6 and 7), the guide film GF may include the cavity CAV. The cavity CAV may function as an alignment key for attaching the display panel DP to the guide film GF. In an embodiment, the cavity CAV may have a visually identifiable shape, for example. The cavity CAV may be a groove structure defined in at least a part of the intermediate portion MP.

The cavity CAV may include a plurality of cavities. In an embodiment, the cavity CAV may include a first cavity defined in the upper left side, a second cavity defined in the lower left side, a third cavity defined in the upper right side, and a fourth cavity defined in the lower right side in a plan view, for example. However, the number of cavities CAV is not limited to the particular example.

In order to closely couple the display panel DP and the cover window portion CV to each other, the display panel DP may be precisely aligned on the intermediate portion MP of the guide film GF. In an embodiment, when the display panel DP is not precisely aligned on the guide film GF, the display panel DP may be coupled (e.g., bonded) to the cover window portion CV in an unintended arrangement, for example. As a result, there may be a risk that the device reliability may be reduced. In an embodiment, durability may be impaired due to incomplete coupling between the display panel DP and the cover window portion CV, for example.

However, in an embodiment, the cavity CAV capable of closely aligning the display panel DP may be formed in the guide film GF, a placement relationship between the guide film GF and the display panel DP may be clearly identified based on the position of the cavity CAV, and the display panel DP may be suitably aligned on the guide film GF.

However, the disclosure is not limited thereto. In an embodiment (FIG. 8), the guide film GF may not include the cavity CAV, for example.

The side portion SP may be formed on opposite sides of the intermediate portion MP. The side portion SP may form the first end portion EP1 and the second end portion EP2. The side portion SP may extend in the first direction DR1.

The side portion SP may include the first side portion SP1 and the second side portion SP2. The first side portion SP1 may be next (adjacent) to the first end portion EP1 and may be formed on a side of the intermediate portion MP. The second side portion SP2 may be next (adjacent) to the second end portion EP2 and may be formed on an opposite side of the intermediate portion MP.

The side portion SP and the intermediate portion MP may define the opening area OPN. The opening area OPNS may penetrate the film base FB (e.g., the first and second film bases FB1 and FB2) in each of the side portions of the side portion SP.

The opening area OPNS may extend in the first direction DR1. In an embodiment, the opening area OPNS may be also referred to as a slit. The opening area OPNS may have a polygonal shape. However, the disclosure is not limited thereto.

In an embodiment, the opening area OPNS may have a width which narrows towards the intermediate portion MP (e.g., the panel placement area PL). When the display panel DP is provided in the panel placement area PL, the area supported by the intermediate portion MP may be expanded so that the display panel DP may be more reliably supported.

The opening area OPNS may be next (adjacent) (e.g., directly next (adjacent)) to the intermediate portion MP. The opening area OPNS may be next (adjacent) (e.g., directly next (adjacent)) to the panel placement area PL. In an embodiment, a portion of the opening area OPNS may be surrounded by the side portion SP, and another portion of the opening area OPNS may be surrounded by the intermediate portion MP, for example. In an embodiment, the opening area OPNS may be recessed into a part of the intermediate portion MP, and may define a groove structure, for example.

When the display panel DP is provided in the panel placement area PL, a portion of the display panel DP may overlap with the intermediate portion MP in a plan view, and another portion of the display panel DP may overlap with the opening area OPNS in a plan view.

In an embodiment, when the display panel DP is provided on the guide film GF, the display panel DP may overlap with the opening area OPNS while being supported by the intermediate portion MP. Accordingly, the risk of process defects (e.g., appearance bubbles, etc.) may be reduced during the coupling process between the cover window portion CV having an inwardly curved shape and the display panel DP.

The opening area OPNS may be provided in plural. In an embodiment, the opening areas OPNS may include a first opening area OPN1 defined in a side of the intermediate portion MP between the first end portion EP1 and the panel placement area PL, and a second opening area OPN2 defined in an opposite side of the intermediate portion MP between the second end portion EP2 and the panel placement area PL, for example.

In an embodiment, the first opening area OPN1 and the second opening area OPN2 may be symmetrical with respect to a center virtual line CL. The center virtual line CL may extend in the second direction DR2 and pass through the center of the intermediate portion MP. The guide film GF may more reliably support the display panel DP.

In an embodiment, the opening areas OPNS may include a plurality of opening areas OPNS spaced apart in the second direction DR2. In an embodiment, the first opening area OPN1 may include a (1-1)th opening area OPN1-1 and a (1-2)th opening area OPN1-2 spaced apart in the second direction DR2, for example. The second opening area OPN2 may include a (2-1)th opening area OPN2-1 and a (2-2)th opening area OPN2-2 spaced apart in the second direction DR2.

In embodiments, the (1-1)th opening area OPN1-1 and the (1-2)th opening area OPN1-2 may have different shapes from each other. However, the disclosure is not limited thereto, and the (1-1)th opening area OPN1-1 and the (1-2)th opening area OPN1-2 may have the same shape as each other.

In an embodiment, the (2-1)th opening area OPN2-1 and the (2-2)th opening area OPN2-2 may have different shapes from each other. However, the disclosure is not limited thereto, and the (2-1)th opening area OPN2-1 and the (2-2)th opening area OPN2-2 may have the same shape as each other.

The side portion SP may form the wing portion WP. The wing portion WP may be formed on opposite sides of the intermediate portion MP, and may support the intermediate portion MP on opposite sides thereof. The wing portion WP may be directly next (adjacent) to each of opposite sides of the intermediate portion MP.

The wing portion WP may include a first wing portion WP1 and a second wing portion WP2. The first wing portion WP1 may be next (adjacent) to the first end portion EP1 and may be formed on a side of the intermediate portion MP. The second wing portion WP2 may be next (adjacent) to the second end portion EP2 and may be formed on an opposite side of the intermediate portion MP.

In an embodiment, the wing portion WP may be formed by the plurality of opening areas OPN. In an embodiment, the first wing portion WP1 may be provided by the (1-1)th opening area OPN1-1 and the (1-2)th opening area OPN1-2 spaced apart in a second direction DR2, for example. The second wing portion WP2 may be provided by the (2-1)th opening area OPN2-1 and the (2-2)th opening area OPN2-2 spaced apart in the second direction DR2.

In an embodiment, the intermediate portion MP may have a smaller width along the second direction DR2 than the side portion SP. The intermediate portion MP may have a first width W1 along the second direction DR2, and the side portion SP may have a second width W2 along the second direction DR2 which is larger than the first width W1. When the display panel DP is disposed within the panel placement area PL, the display panel DP may not extend beyond the outer periphery of the guide film GF based on the width direction of the guide film GF, or the likelihood that a portion of the display panel DP may not be appropriately pushed by the guide film GF may be reduced.

The adhesive layer ADS may be disposed within the intermediate portion MP. In an embodiment, the adhesive layer ADS may be disposed within the panel placement area PL, for example. The adhesive layer ADS may be disposed on the first film base FB1. The adhesive layer ADS may be disposed within the film opening area FOP defined by the second film base FB2.

The adhesive layer ADS may fix a position of the display panel DP on the guide film GF when the display panel DP is provided on the guide film GF. The adhesive layer ADS may or may not be exposed to the outside, depending on whether the temporary cover portion TC is removed. The adhesive layer ADS may include various resin materials, including adhesive materials, and embodiments of adhesive materials are not limited to any particular example.

The temporary cover portion TC may removably cover the adhesive layer ADS. The temporary cover portion TC may cover the adhesive layer ADS and may be removable from the adhesive layer ADS to allow the display panel DP to be disposed on the adhesive layer ADS. The temporary cover portion TC may not expose the adhesive layer ADS before the display panel DP is disposed within the panel placement area PL.

The temporary cover portion TC may include a handle portion HP and an adhesive cover portion AC.

The handle portion HP may extend outward from the intermediate portion MP when the temporary cover portion TC covers the adhesive layer ADS, and may provide an external force through the handle portion HP to cause the temporary cover portion TC to be spaced apart from the adhesive layer ADS.

The adhesive cover portion AC is connected to the handle portion HP, and may cover (e.g., completely cover) the adhesive layer ADS. The adhesive cover portion AC may have the same shape as that of the intermediate portion MP (or the panel placement area PL), and may have a similar area to the intermediate portion MP (or the panel placement area PL).

In embodiments, when the temporary cover portion TC covers the adhesive layer ADS, at least a part of the temporary cover portion TC (or the adhesive cover portion AC) may overlap with the opening area OPNS in a plan view.

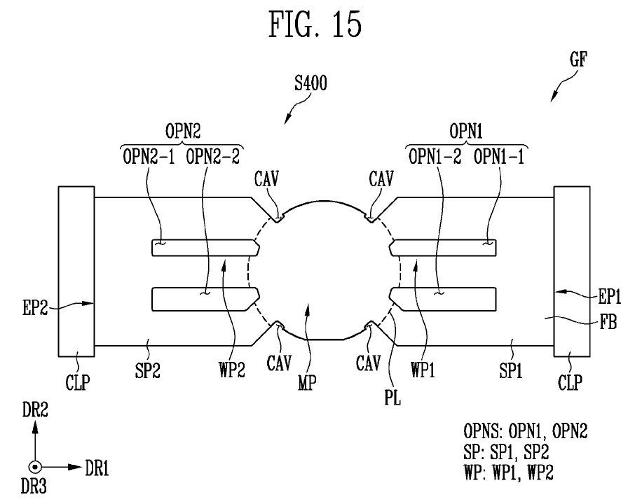

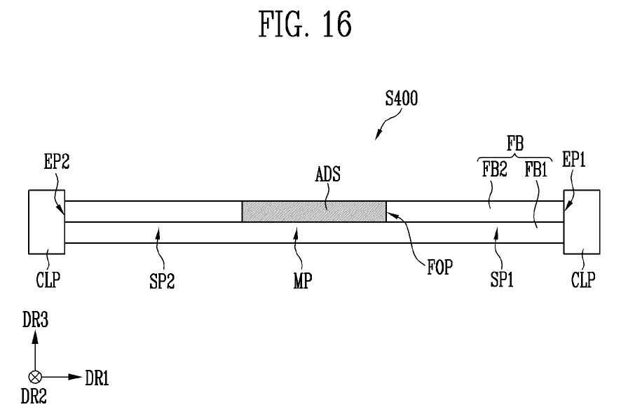

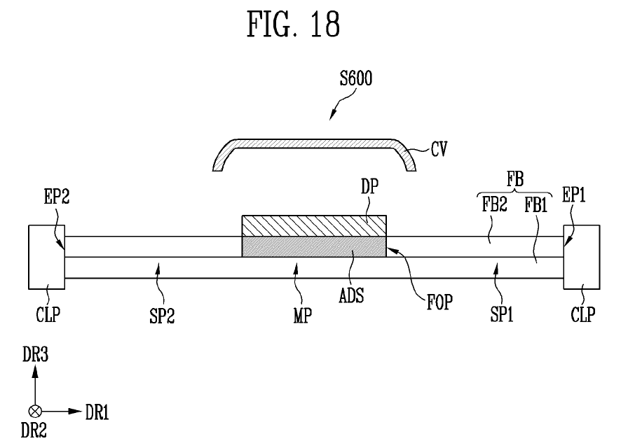

Referring to FIGS. 12-21, a method of manufacturing the electronic device ED using the guide film GF in an embodiment will be described. For the sake of simplicity of explanation, descriptions which may overlap with the foregoing will be schematically illustrated or omitted. Furthermore, for convenience of explanation, a manufacturing method of the electronic device ED will be described based on a method of manufacturing the watch device 1.

FIG. 12 is a schematic flowchart illustrating an embodiment of a manufacturing method of an electronic device (e.g., a watch device) using a guide film. FIGS. 13-21 are schematic diagrams illustrating respective operations of a method of manufacturing an electronic device (e.g., a watch device) using a guide film. In an embodiment, the process method including operations S200, S400, S600, S800, and S900 to be described below may be also referred to as a method of coupling the display panel DP and the cover window portion CV.

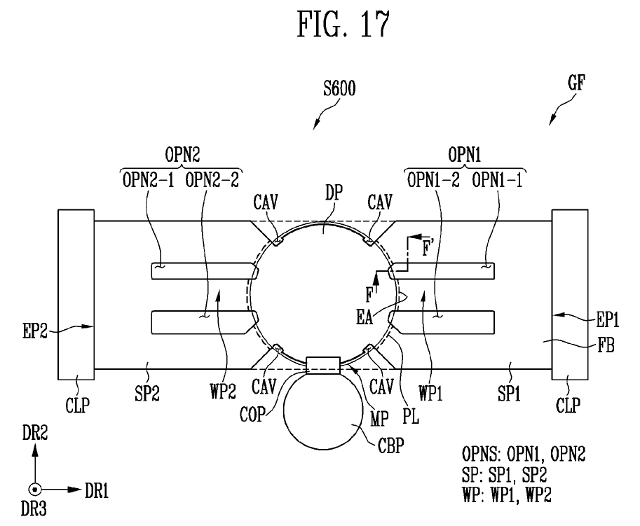

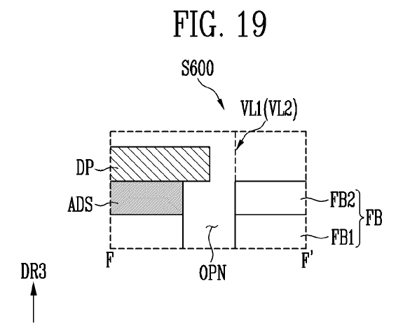

For ease of explanation, FIGS. 13, 15, and 17 schematically illustrate process operations based on the planar structure of the guide film GF as shown in FIGS. 6 and 7. For ease of explanation, FIGS. 14, 16, 18, 20, and 21 schematically illustrate process operations based on the cross-sectional structure of the guide film GF as shown in FIG. 9. FIG. 19 is a schematic cross-sectional view taken along line F-F’ of FIG. 17.

Referring to FIG. 12, a method of manufacturing the electronic device ED (e.g., the watch device 1) using the guide film GF in an embodiment may include a process of providing a guide film in operation S200, a process of removing a temporary cover portion in operation S400, a process of disposing a display panel on the guide film in operation S600, a process of coupling the cover window portion and the display panel in operation S800, and a process of separating the display panel and the guide film in operation S900.

Referring to FIGS. 12 to 14, in operation S200 of providing a guide film, the guide film GF may be prepared.

In operation S200, the temporary cover portion TC may cover the adhesive layer ADS, and a top surface of the adhesive layer ADS may not be exposed.

In operation S200, the clamp portion CLP may secure the first and second end portions EP1 and EP2 of the guide film GF. The position of the guide film GF may be fixed by the clamp portion CLP.

Referring to FIGS. 12, 15, and 16, in operation S400 of removing a temporary cover portion, the temporary cover portion TC may be removed, and an outer surface of the adhesive layer ADS may be exposed.

In operation S400, when the position of the guide film GF is fixed by the clamp portion CLP, the temporary cover portion TC may be spaced apart (e.g., separated) from the adhesive layer ADS. In an embodiment, the adhesive cover portion AC may be efficiently detached from the adhesive layer ADS using the handle portion HP.

Accordingly, in operation S400, the guide film GF may be prepared in a state in which the display panel DP is attachable thereto. In an embodiment, in operation S400, a surface of the adhesive layer PL in the panel placement area PL may be exposed, for example.

Referring to FIGS. 12, 17, 18, and 19, in operation S600 of disposing a display panel on the guide film, the display panel DP may be disposed on the adhesive layer ADS.

In operation S600, the display panel DP may be disposed on the intermediate portion MP. The display panel DP may be disposed on the adhesive layer ADS in the panel placement area PL. The display panel DP may be disposed at a fixed position on the guide film GF by the adhesive layer ADS.

In operation S600, the position of the guide film GF may be precisely determined by the cavities CAV, and based on the determined position of the guide film GF, the display panel DP may be aligned to an intended position and orientation within the panel placement area PL.

In operation S600, the display panel DP may be coupled (e.g., bonded) to the circuit board portion CBP by the connection portion COP. The connection portion COP may be disposed on a surface of a portion of the display panel DP, and a lower surface of the display panel DP may be attached to the adhesive layer ADS. The connection portion COP may be formed on a side different from the side on which the handle portion HP of the temporary cover portion TC is disposed.

In operation S600, the display panel DP may overlap with the opening area OPNS in a plan view (e.g., along the third direction DR3), and may be supported by the intermediate portion MP. Accordingly, a portion of the lower surface of the display panel DP may be supported by the guide film GF, and another portion of the lower surface of the display panel DP may be opened by the opening area OPN.

In operation S600, the display panel DP may be disposed in a fixed position relative to the guide film GF, and an end portion of the display panel DP may not protrude (or extend) outward beyond a first virtual line VL1 and a second virtual line VL2. The end portion of the display panel DP may be formed inward of the first virtual line VL1 and the second virtual line VL2. The risk that a portion of the display panel DP is not properly pushed by the guide film GF may be reduced, and the risk that a portion of the display panel DP is not properly coupled (e.g., bonded) to the cover window portion CV in a subsequent process may be reduced.

The first virtual line VL1 and the second virtual line VL2 may be defined alongside surfaces of the first side portion SP1 and the second side portion SP2 extending in the first direction DR1.

When the display panel DP is disposed in the panel placement area PL in operation S600, a portion of the panel placement area PL may not be covered by the display panel DP, and a separation area EA which is a portion of the panel placement area PL may be exposed. In embodiments, the panel placement area PL may have an area greater than or equal to the display panel DP, thereby allowing the display panel DP to be adequately attached to the adhesive layer ADS with greater reliability.

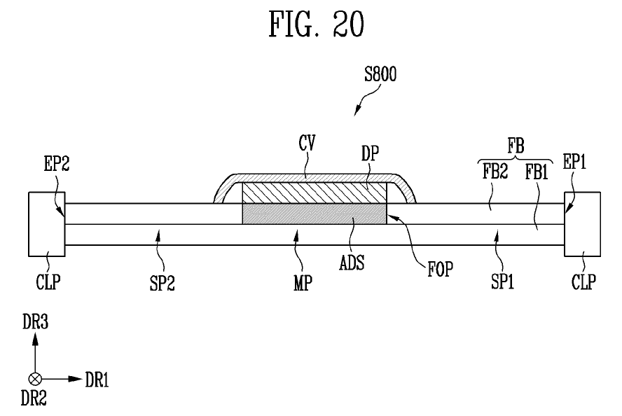

Referring to FIGS. 12 and 20, in operation S800 of coupling the cover window portion and the display panel, the cover window portion CV and the display panel DP may be next (adjacent) to each other and may be coupled (e.g., bonded) to each other.

In operation S800, when a lower portion of the display panel DP is supported by the guide film GF, the cover window portion CV and the display panel DP may be moved to be next (adjacent) to each other. Accordingly, the display panel DP may be pushed in the third direction DR3 so that the cover window portion CV and the display panel DP may be coupled (e.g., bonded) to each other. In an embodiment, as described above, a transparent adhesive layer may be interposed between the cover window portion CV and the display panel DP, for example.

In an embodiment, the display panel DP fixed by the guide film GF including the opening area OPNS or the like may be suitably coupled (e.g., bonded) to the cover window portion CV having a curved structure.

Experimentally, when the display panel DP is provided within the curved region of the cover window portion CV, a possibility may arise that a portion of the display panel DP is not suitably attached to the cover window portion CV due to the curved region of the inner surface of the cover window portion CV.

However, in an embodiment, the guide film GF may push the display panel DP in a state that a portion of the lower surface of the display panel DP is opened through the opening area OPN, so that interference by the bending of the cover window portion CV around the periphery of the end portion of the display panel DP may not occur. Accordingly, the coupling between the display panel DP and the cover window portion CV may be suitably accomplished. Furthermore, the risk of bubbles or the like being generated between the display panel DP and the cover window portion CV may be reduced, thereby improving the display quality of the display part 100 and the reliability of the device.

Furthermore, since the display panel DP and the cover window portion CV may be suitably coupled (e.g., bonded) by the opening area OPNS of the guide film GF, and the lower surface of the display panel DP may be supported by the intermediate portion MP forming the panel placement area PL, the stability of the placement of the display panel DP during the manufacturing process may be improved. As a result, process efficiency may be improved as the risk of the position and orientation of the display panel DP may be reduced during the processes.

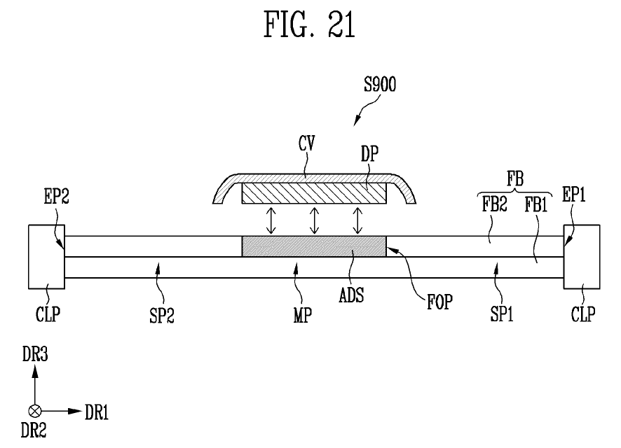

Referring to FIGS. 12 and 21, in operation S900 of separating the display panel and the guide film, the guide film GF may be separated from the display panel DP while the cover window portion CV and the display panel DP are coupled (e.g., bonded) to each other.

In operation S900, the adhesive layer ADS may be separated from the display panel DP, and a coupling structure may be formed between the display panel DP and the cover window portion CV.

Subsequently, in an embodiment, the circuit board portion CBP may be coupled (e.g., bonded) to the rear surface of the display panel DP, and the lower base LB may be disposed on the lower portion of the display panel DP. The display panel DP may form the display part 100, so that the electronic device ED in an embodiment may be provided. In an embodiment, the display part 100 may be coupled (e.g., bonded) to the strap part 200. As a result, the watch device 1 in an embodiment may be provided.

By embodiments of the disclosure, a guide film, a manufacturing method of an electronic device using the guide film, and an electronic device manufactured by the manufacturing method of the electronic device, in which a display panel and a cover window included in the electronic device may be closely coupled (e.g., bonded) to each other, may be provided.

In an embodiment of the disclosure, a guide film, a method of manufacturing an electronic device using the guide film, and an electronic device manufactured by the method of manufacturing the electronic device may be provided, in which the convenience of a process for coupling a display panel and a cover window may be improved, and the reliability of the process may be improved by precisely aligning the display panel may be provided.

The disclosure should not be construed as being limited to the embodiments set forth herein. Rather, these embodiments are provided to enable a thorough and complete disclosure and to fully convey the concept of the disclosure to those skilled in the art.

While the disclosure has been particularly shown and described with reference to embodiments thereof, it will be understood by those of ordinary skill in the art that various changes in form and detail may be made therein without departing from the spirit or scope of the disclosure as defined by the following claims.

What is claimed is:

1. A guide film, comprising:
a film base comprising:
an intermediate portion;
side portions formed on opposite sides of the intermediate portion, respectively,
wherein an opening area is defined directly next to the intermediate portion.

2. The guide film of claim 1, wherein the side portions comprise a first side portion and a second side portion, and
wherein the intermediate portion is disposed between the first side portion and the second side portion relative to a longitudinal direction of the guide film, and forms a panel placement area in which a display panel is disposed.

3. The guide film of claim 2, wherein the intermediate portion and the display panel have a same shape as each other, and
wherein the panel placement area has an area greater than or equal to a lower surface of the display panel.

4. The guide film of claim 2, wherein when the display panel is disposed in the panel placement area, a lower surface of the display panel is supported by the intermediate portion, and at least a portion of the lower surface of the display panel is opened by the opening area.

5. The guide film of claim 2, further comprising:
an adhesive layer disposed on a portion of the film base; and
a temporary cover portion removably covering the adhesive layer.

6. The guide film of claim 5, wherein the film base comprises a first film base and a film opening area defined in the first film base and exposing the first film base,
wherein the adhesive layer is disposed on the first film base in the film opening area, and
wherein the temporary cover portion comprises an adhesive covering portion covering the panel placement area and a handle portion connected to the adhesive covering portion and extending outward from the intermediate portion.

7. The guide film of claim 1, wherein the opening area extends in a longitudinal direction of the guide film and penetrates the film base at each of the side portions.

8. The guide film of claim 1, wherein the opening area has a width decreasing toward the intermediate portion.

9. The guide film of claim 1, wherein a part of the opening area is surrounded by the side portions, and another part of the opening area is surrounded by the intermediate portion, and
wherein the opening area defines a groove structure recessed into a part of the intermediate portion.

10. The guide film of claim 1, wherein the side portions comprise a first side portion and a second side portion,
wherein the opening area comprises a first opening area defined in the first side portion and a second opening area defined in the second side portion, and
wherein the first opening area and the second opening area are symmetrical with respect to a central virtual line extending in a width direction of the guide film and passing through a center of the intermediate portion.

11. The guide film of claim 1, wherein the opening area is provided in plural, and
wherein each of the side portions comprises a wing portion formed between the plurality of opening areas in a width direction of the guide film.

12. The guide film of claim 1, further comprising a cavity comprising a groove structure defined in at least a part of the intermediate portion, the cavity being visually identifiable.

13. The guide film of claim 12, wherein in a plan view, the cavity comprises a first cavity defined in an upper left part of the intermediate portion, a second cavity defined in a lower left part of the intermediate portion, a third cavity defined in an upper right part of the intermediate portion, and a fourth cavity defined in a lower right part of the intermediate portion.

14. A method of manufacturing an electronic device, the method comprising:
providing a guide film comprising a film base which comprises an intermediate portion and side portions formed on opposite sides of the intermediate portion and in which an opening area is defined directly next to the intermediate portion;
disposing a display panel on the guide film; and
coupling the display panel and a cover window portion.

15. The method of claim 14, wherein the guide film further comprises: an adhesive layer disposed on a portion of the film base; and a temporary cover portion removably covering the adhesive layer,
wherein the providing the guide film comprises securing both end portions of the guide film by a clamp portion and covering the adhesive layer by the temporary cover portion, and
wherein the disposing the display panel comprises separating the temporary cover portion from the adhesive layer to expose the adhesive layer and disposing the display panel on the adhesive layer.

16. The method of claim 14, wherein the guide film further comprises a cavity comprising a groove structure defined in at least a part of the intermediate portion, the cavity being visually identifiable, and
wherein the disposing the display panel comprises determining the guide film using the cavity.

17. The method of claim 14, wherein in the disposing the display panel, a portion of the display panel overlaps with the opening area and another portion of the display panel overlaps with the intermediate portion in a plan view.

18. The method of claim 14, wherein in the disposing the display panel, the display panel is disposed at a fixed position relative to the guide film, an end portion of the display panel does not protrude outward beyond a virtual line, and the virtual line is defined along side surfaces of the side portions extending in a longitudinal direction of the guide film.

19. The method of claim 14, further comprising separating the display panel from the guide film,
wherein the cover window portion comprises a first portion and a second portion integral with the first portion and comprising a curved area and surrounding edges of the first portion, and at least a part of the second portion extends in a thickness direction of the display panel.

20. The electronic device manufactured by the method of claim 14, wherein the cover window portion is inwardly curved toward the display panel.
